(19) United States
(12) Patent Application Publication
(10) Pub. No.: US 2023/0036268 A1
(43) Pub. Date: Feb. 2, 2023

(54) PROBE AND PROBE CARD DEVICE

(71) Applicant: TECAT TECHNOLOGIES (SUZHOU) LIMITED, Suzhou (CN)

(72) Inventor: CHOON LEONG LOU, SINGAPORE (SG)

(21) Appl. No.: 17/405,508

(22) Filed: Aug. 18, 2021

(30) Foreign Application Priority Data
Jul. 29, 2021 (CN) 202110863757.3

(51) Int. Cl. G01R 1/073; G01R 1/067

(52) U.S. Cl. CPC G01R 1/07342; G01R 1/06738; G01R 31/2887

(57) ABSTRACT

The present disclosure provides a probe and a probe card device. The probe card device includes a first plate and a plurality of probes. The probes are arranged through the first plate, and include a first probe and a second probe. The first probe has a first body and an end portion of the first body. The end portion of the first body has a first recess and a first protrusion. The second probe has a second body and an end portion of the second body. The end portion of the second body has a second recess and a second protrusion. The second protrusion extends into the first recess.

### TECHNICAL FIELD

The present disclosure relates to a probe and a probe card device, and more particularly, to a probe and a probe card device for testing electronic devices.

### DISCUSSION OF THE BACKGROUND

An electrical test of an integrated circuit chip (IC chip) is an important step in the manufacturing process. Each IC chip needs to be tested at both wafer level and package level to ensure its electrical function. For testing the electrical function of the IC chip, a test machine equipped with a probe card device is introduced.

In particular, the probe card device has a plurality of probes (i.e., probing pins), and the test machine contacts and tests a device under test (DUT) through the probes of the probe card device. However, the minimum size of the DUT may be limited since pitches between the probes cannot be reduced.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a probe. The probe includes a body and an end portion of the body. The end portion of the body has a protrusion and a recess. The protrusion is disposed on a first side of the end portion. The recess is formed on a second side of the end portion. A dimension of the recess is greater than a dimension of a top portion of the protrusion.

In some embodiments, the first side is opposite to the second side.

In some embodiments, the protrusion protrudes away from the end portion and the recess is concave toward the end portion.

In some embodiments, a depth of the recess is greater than a thickness of the top portion of the protrusion.

In some embodiments, a depth of the recess is about 5% to 30% of a width of the end portion.

In some embodiments, a length of an opening of the recess is greater than a length of the top portion of the protrusion.

In some embodiments, the recess is tapered from outside of the end portion to inside the end portion.

In some embodiments, a shape of the recess includes a trapezoid, an arc or a rectangle.

In some embodiments, a shape of the protrusion corresponds to the shape of the recess.

Another aspect of the present disclosure provides a probe. The probe includes a body and an end portion of the body. The end portion of the body has a protrusion and a recess. The recess has a shape for accommodating another protrusion of another probe.

In some embodiments, the recess and the another protrusion of the another probe are near each other when the probe and the another probe are arranged in an array and the shape of the recess accommodates the another protrusion of the another probe.

In some embodiments, a position of the recess corresponds to a position of the another protrusion of the another probe when the probe and the another probe are arranged in an array.

Another aspect of the present disclosure provides a probe card device. The probe card device includes a first plate and a plurality of probes. The probes are arranged through the first plate, and include a first probe and a second probe. The first probe has a first body and an end portion of the first body. The end portion of the first body has a first recess and a first protrusion. The second probe has a second body and an end portion of the second body. The end portion of the second body has a second recess and a second protrusion. The second protrusion extends into the first recess.

In some embodiments, a distance between the end portion of the first body and the end portion of the second body is less than a thickness of the second protrusion.

In some embodiments, a shape of the second protrusion corresponds to a shape of the first recess.

In some embodiments, a position of the second protrusion corresponds to a position of the first recess.

In some embodiments, the first recess and the second protrusion are near each other.

In some embodiments, the first plate has a plurality of first through holes for receiving the probes.

In some embodiments, the probe card device further includes a second plate. The second plate is parallel to the first plate and has a plurality of second through holes for receiving the probes.

In some embodiments, the first through hole and the second through hole receiving a same probe are offset as viewed from a direction which is perpendicular to the first plate and the second plate.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1A is a schematic view of a probe according to some embodiments of the present disclosure.

FIG. 1B is an enlarged view of an end portion of a body of a probe according to an embodiment of the present disclosure.

FIG. 1C is a schematic view of a probe array of probes according to some embodiments of the present disclosure.

FIG. 2A is a schematic view of a probe according to some embodiments of the present disclosure.

FIG. 2B is an enlarged view of an end portion of a body of a probe according to an embodiment of the present disclosure.

FIG. 2C is a schematic view of a probe array of probes according to some embodiments of the present disclosure.

FIG. 3A is a schematic view of a probe according to some embodiments of the present disclosure.

FIG. 3B is a schematic view of a probe array of probes according to some embodiments of the present disclosure.

FIG. 3C is a schematic view of a probe according to some embodiments of the present disclosure.

FIG. 3D is a schematic view of a probe array of probes according to some embodiments of the present disclosure.

FIG. 3E is a schematic view of a probe according to some embodiments of the present disclosure.

FIG. 3F is a schematic view of a probe array of probes according to some embodiments of the present disclosure.

FIG. 3G is a schematic view of a probe according to some embodiments of the present disclosure.

FIG. 3H is a schematic view of a probe array of probes according to some embodiments of the present disclosure.

FIG. 4A is a schematic view of a probe card device according to some embodiments of the present disclosure.

FIG. 4B is a schematic view of a probe of a probe card device according to some embodiments of the present disclosure.

FIG. 4C is an enlarged view of an end portion of a body of a probe according to an embodiment of the present disclosure.

FIG. 4D is a schematic view of two adjacent probes of a probe card device according to some embodiments of the present disclosure.

### DETAILED DESCRIPTION

The following description of the disclosure accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

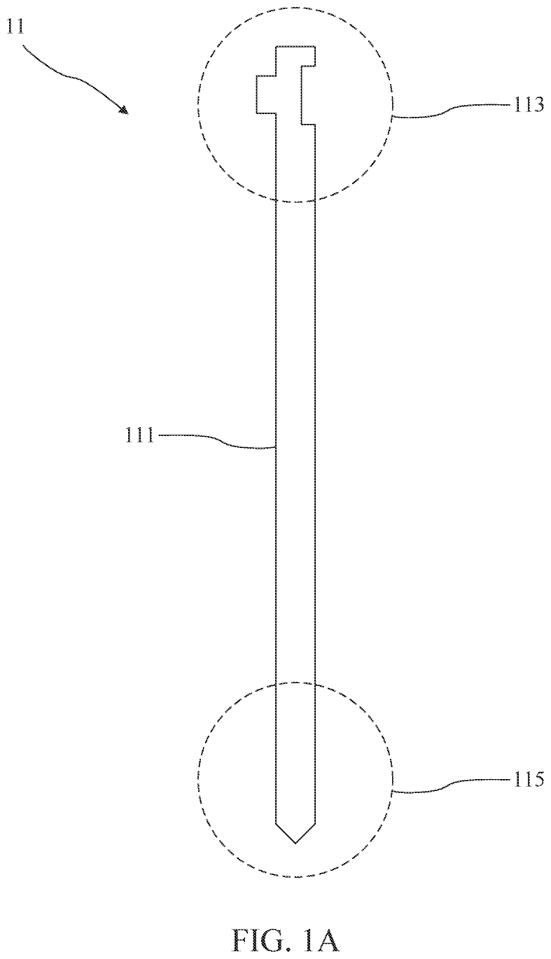

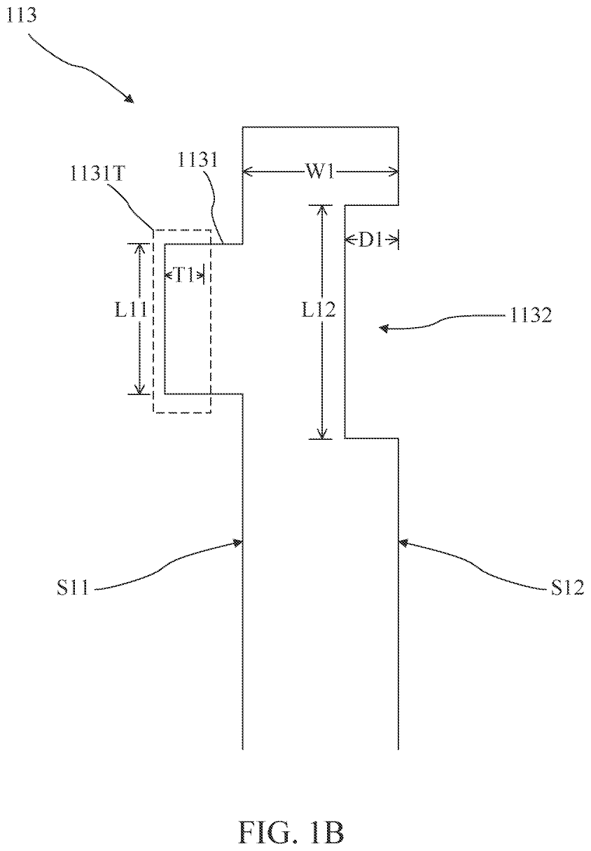

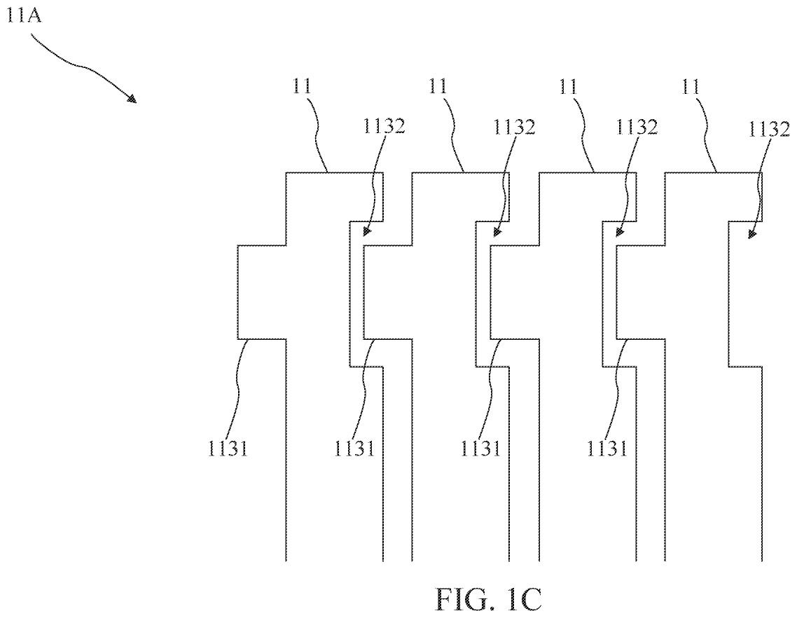

Please refer to FIGS. 1A and 1B. FIG. 1A is a schematic view of a probe 11 according to some embodiments of the present disclosure. The probe 11 may include a body 111 and two end portions 113, 115 of the body 111. The end portions 113 and 115 may be opposite. The end portion 115 may be a tip to touch an integrated circuit (IC) chip (not shown) for testing. FIG. 1B is an enlarged view of the end portion 113 of the body 111 according to an embodiment of the present disclosure. The end portion 113 may include a protrusion 1131 and a recess 1132. In such embodiments, the protrusion 1131 and the recess 1132 may have rectangular shapes.

In detail, the end portion 113 may have two sides S11 and S12 which are opposite. The protrusion 1131 may be disposed on the side S11 of the end portion 113 and protrude away from the end portion 113. The recess 1132 may be formed on the side S12 of the end portion 113 and be concave toward the end portion 113.

In some embodiments, a dimension of the recess 1132 may be greater than a dimension of a top portion 1131T of the protrusion 1131. In some implementations, a length L12 of an opening of the recess 1132 may be greater than a length L11 of the top portion 1131T of the protrusion 1131. In some implementations, a depth D1 of the recess 1132 may be greater than a thickness T1 of the top portion 1131T of the protrusion 1131.

Accordingly, when the probes 11 are arranged in a probe array, the recess 1132 of the probe 11 may accommodate a protrusion 1131 of another probe 11 because the dimension of the recess 1132 is greater than the dimension of the top portion 1131T of the protrusion 1131.

Please refer to FIG. 1C, which is a schematic view of a probe array 11A of the probes 11 according to some embodiments of the present disclosure. Specifically, when the probes 11 are arranged in the probe array 11A, a position of the recess 1132 may correspond to a position of the protrusion 1131 of another probe 11, and the recess 1132 may have a shape for accommodating the protrusion 1131 of the another probe 11.

Further, when the recess 1132 accommodates the protrusion 1131 of the another probe 11, the recess 1132 and the protrusion 1131 of the another probe 11 are near each other and should be separated to prevent the probes 11 from short circuiting. In other words, the recess 1132 and the protrusion 1131 of the another probe 11 are contactless.

In some embodiments, for the purpose of controlling the electrical characteristic of the probe 11 to function well, a ratio of the depth D1 of the recess 1132 and a width W1 of the end portion 113 may not be greater than a threshold.

For example, the depth D1 of the recess 1132 may be about 5% to 30% of the width W1 of the end portion 113. For another example, the depth D1 of the recess 1132 may be about 10% to 20% of the width W1 of the end portion 113.

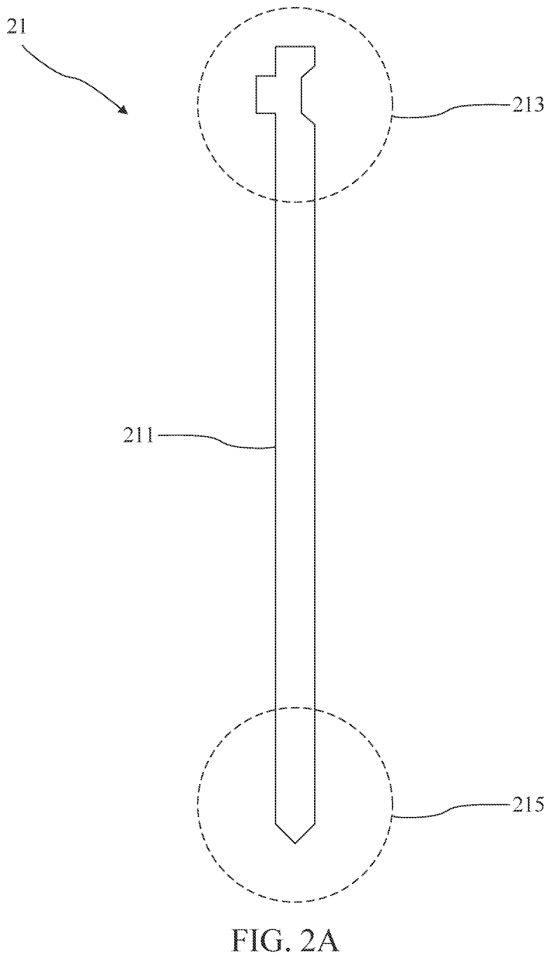

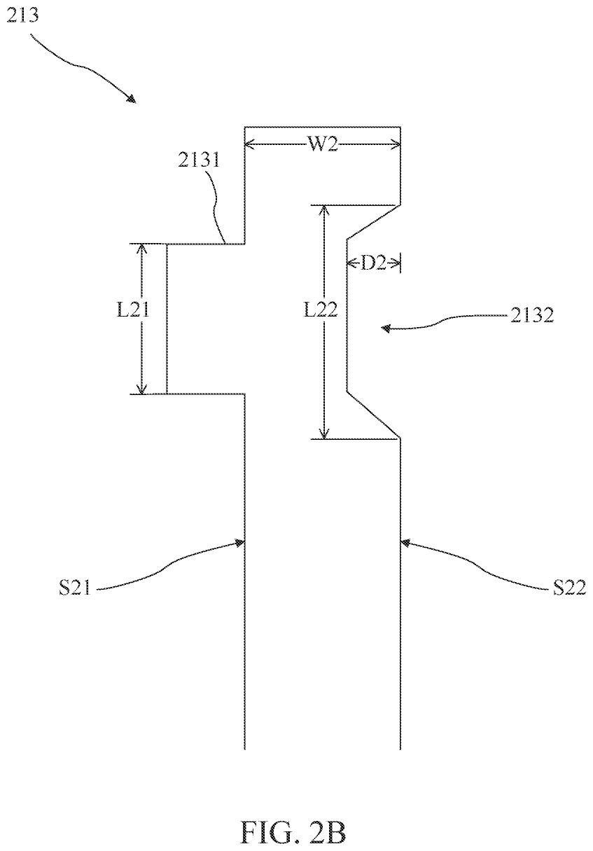

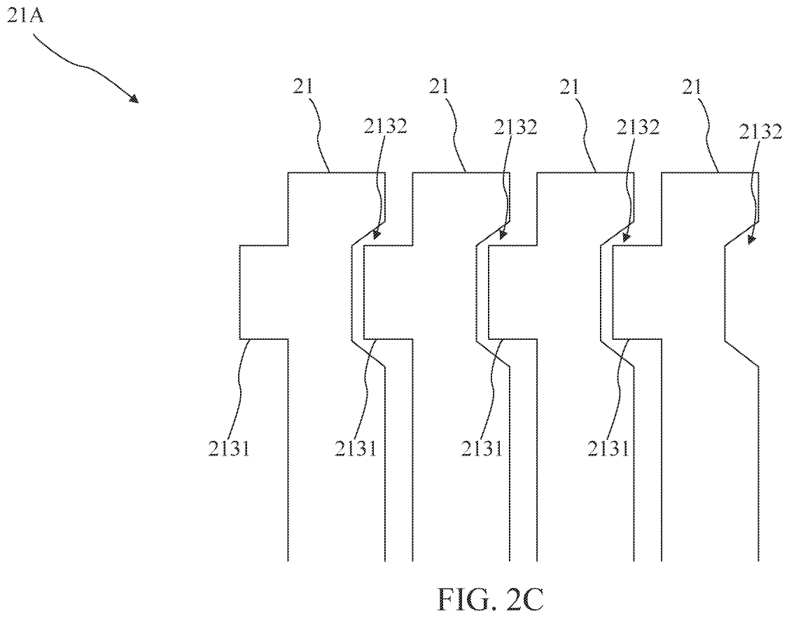

Please refer to FIGS. 2A and 2B. FIG. 2A is a schematic view of a probe 21 according to some embodiments of the present disclosure. The probe 21 may include a body 211 and end portions 213, 215 of the body 211. The end portions 213 and 215 may be opposite. The end portion 215 may be a tip to touch an IC chip (not shown) for testing. FIG. 2B is an enlarged view of the end portion 213 of the body 211 according to an embodiment of the present disclosure. The end portion 213 may include a protrusion 2131 and a recess 2132. In such embodiments, the recess 2132 may be tapered from outside of the end portion 213 to inside of the end portion 213.

In detail, the end portion 213 may have two sides S21 and S22 which are opposite. The protrusion 2131 may be disposed on the side S21 of the end portion 213 and protrude away from the end portion 213. The recess 2132 may be formed on the side S22 of the end portion 213 and be concave toward the end portion 213.

In some embodiments, a dimension of the recess 2132 may be greater than a dimension of a part of the protrusion 2131. In some implementations, a length L22 of an opening of the recess 2132 may be greater than a length L21 of a part of the protrusion 2131.

Accordingly, when the probes 21 are arranged in a probe array, the recess 2132 of the probe 21 may accommodate the part of the protrusion 2131 of another probe 21 because the dimension of the recess 2132 is greater than the dimension of the part of the protrusion 2131.

Please refer to FIG. 2C, which is a schematic view of a probe array 21A of the probes 21. Specifically, when the probes 21 are arranged in the probe array 21A, a position of the recess 2132 may correspond to a position of the protrusion 2131 of another probe 21, and the recess 2132 may have a shape for accommodating the part of the protrusion 2131 of the another probe 21.

Further, when the recess 2132 accommodates the part of the protrusion 2131 of the another probe 21, the recess 2132 and the protrusion 2131 of the another probe 21 are near each other and should be separated from each other to prevent the probes 21 from short circuiting. In other words, the recess 2132 and the protrusion 2131 of the another probe 21 are contactless.

In some embodiments, for the purpose of controlling the electrical characteristic of the probe 21 to function well, a ratio of a depth D2 of the recess 2132 and a width W2 of the end portion 213 may not be greater than a threshold.

For example, the depth D2 of the recess 2132 may be about 5% to 30% of the width W2 of the end portion 213. For another example, the depth D2 of the recess 2132 may be about 10% to 20% of the width W2 of the end portion 213.

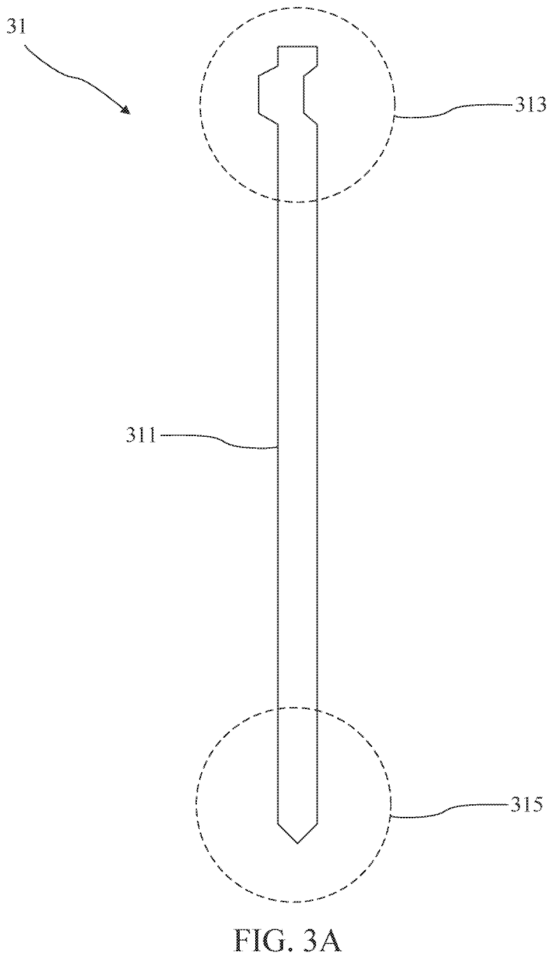

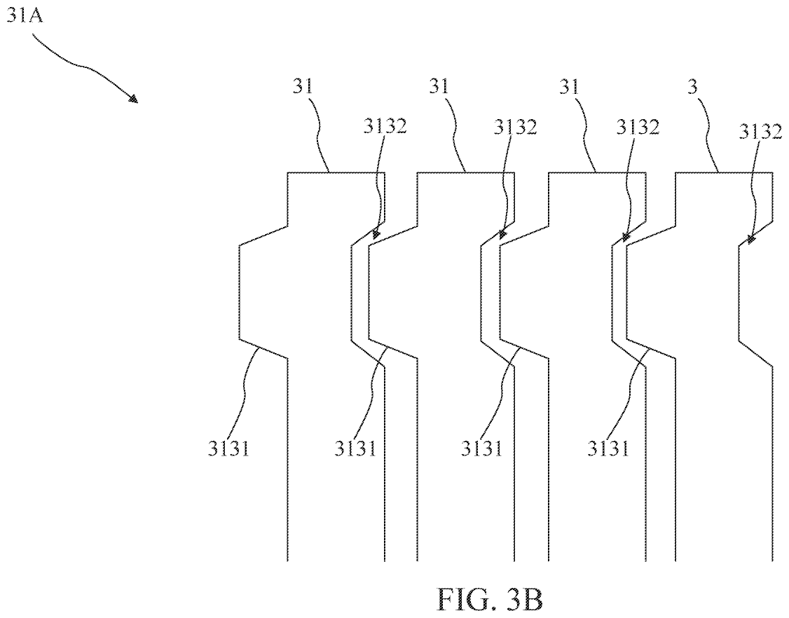

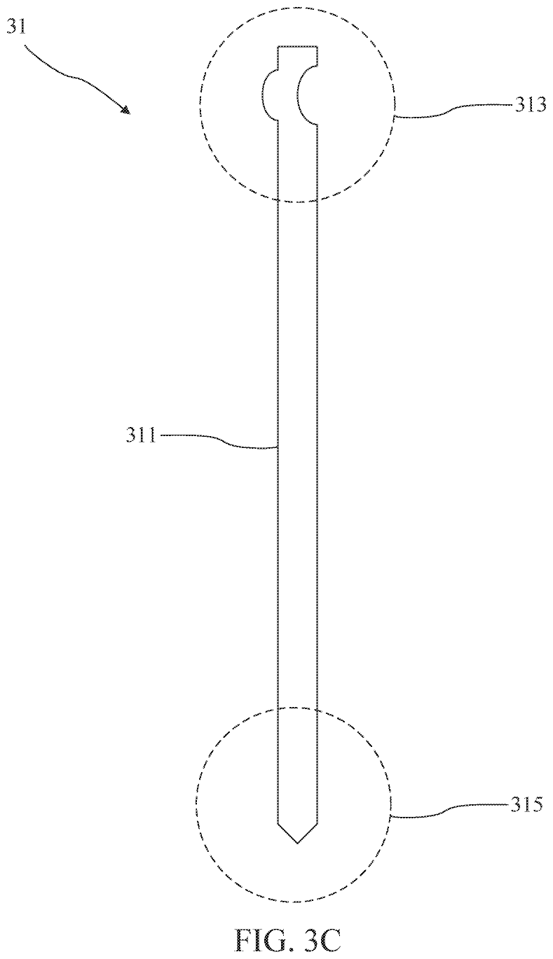

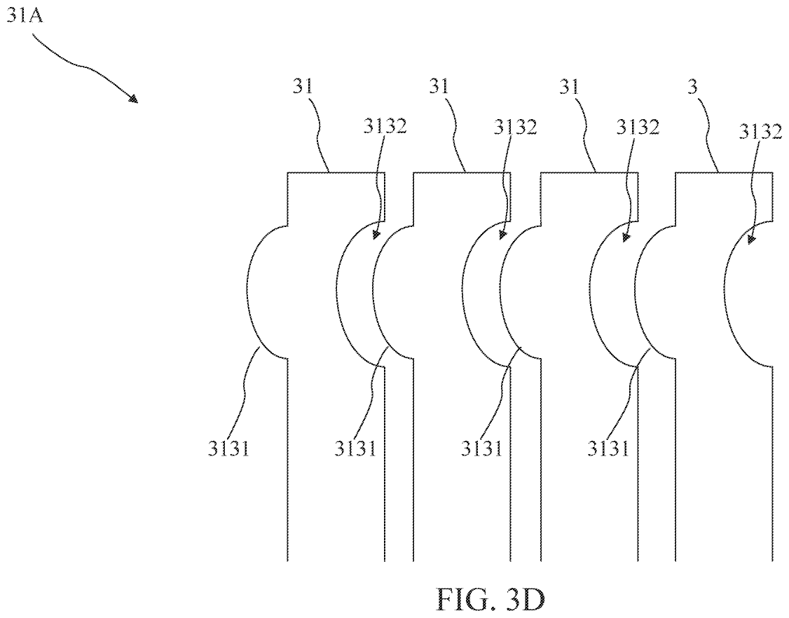

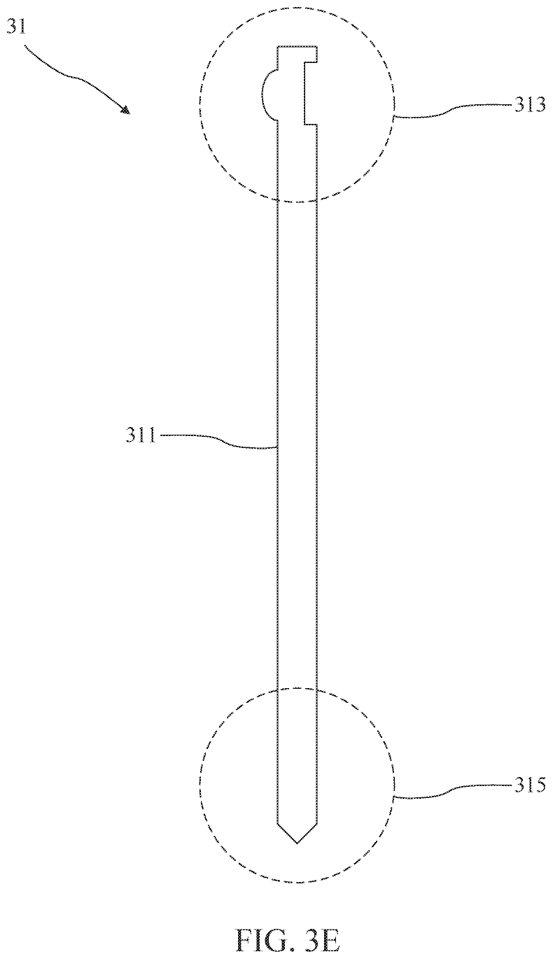

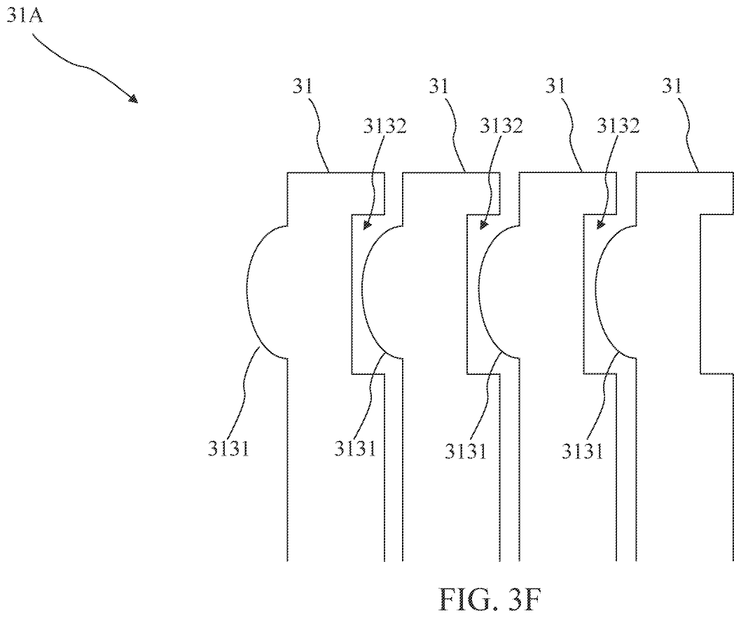

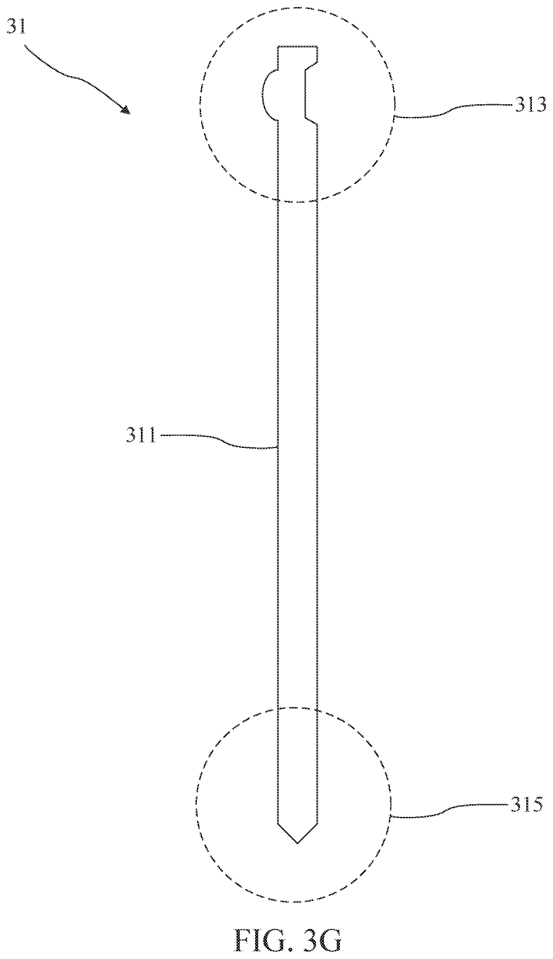

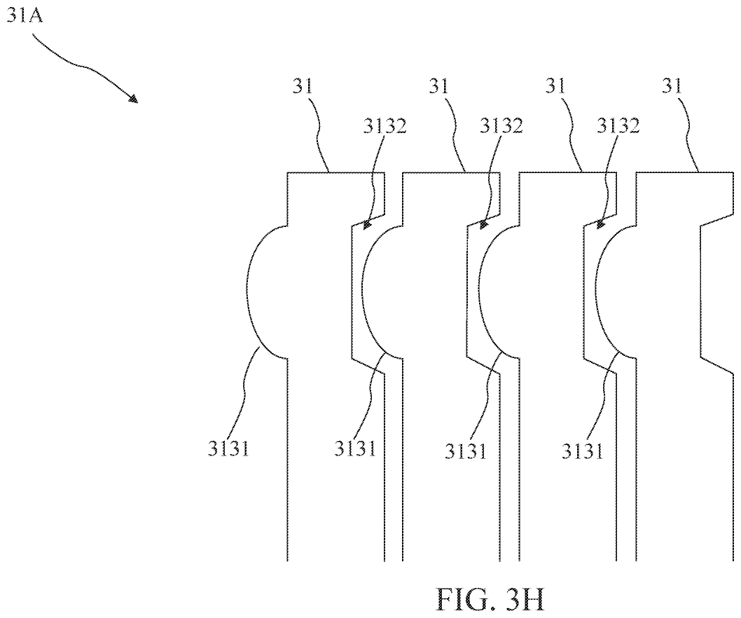

Please refer to FIGS. 3A to 3H, which are schematic views of different structures of probes 31 and probe arrays 31A according to some embodiments of the present disclosure. In particular, each of the probes 31 may include a body 311 and end portions 313, 315 of the body 311. The end portions 313 and 315 may be opposite. The end portion 315 may be a tip to touch an IC chip (not shown) for testing. The end portion 313 may include a protrusion 3131 and a recess 3132.

In some embodiments, the shape of the protrusion 3131 may correspond to the shape of the recess 3132. As shown in FIGS. 3A and 3B, the shapes of the protrusion 3131 and the recess 3132 may be trapezoidal. As shown in FIGS. 3C and 3D, the protrusion 3131 and the recess 3132 may be arc-shaped.

In some embodiments, the shape of the protrusion 3131 may be different from the shape of the recess 3132. As shown in FIGS. 3E and 3F, the protrusion 3131 may be arc-shaped and the recess 3132 may be rectangular. As shown in FIGS. 3G and 3H, the protrusion 3131 may be arc-shaped and the recess 3132 may be trapezoidal.

It should be noted that the mentioned embodiments of the protrusion 3131 and the recess 3132 are not intended to limit the protrusion 3131 and the recess 3132 to any shape. The concept of the present application is that the shape of the recess of the probe may have enough space to accommodate the shape of the protrusion of another probe so as to reduce pitches between the probes of the probe array.

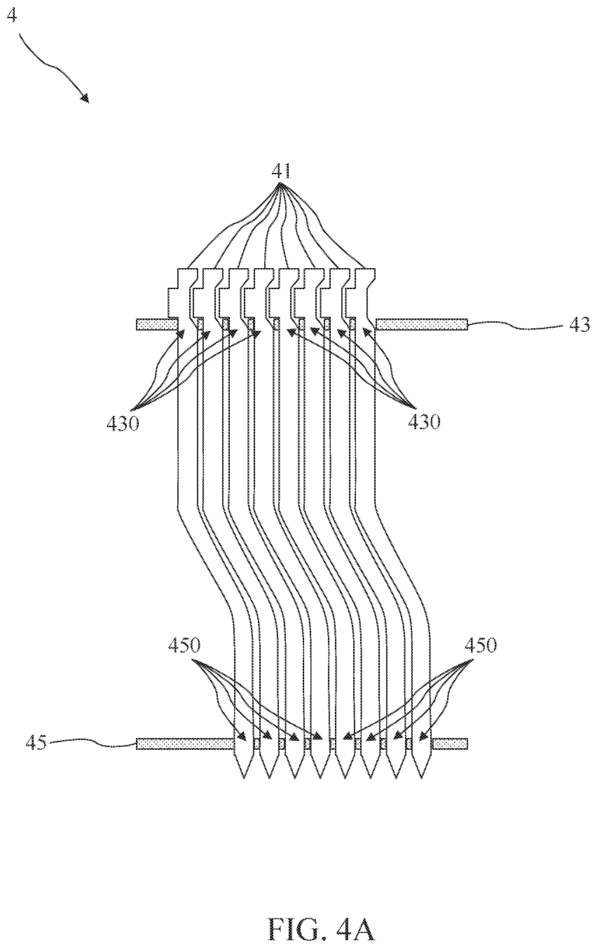

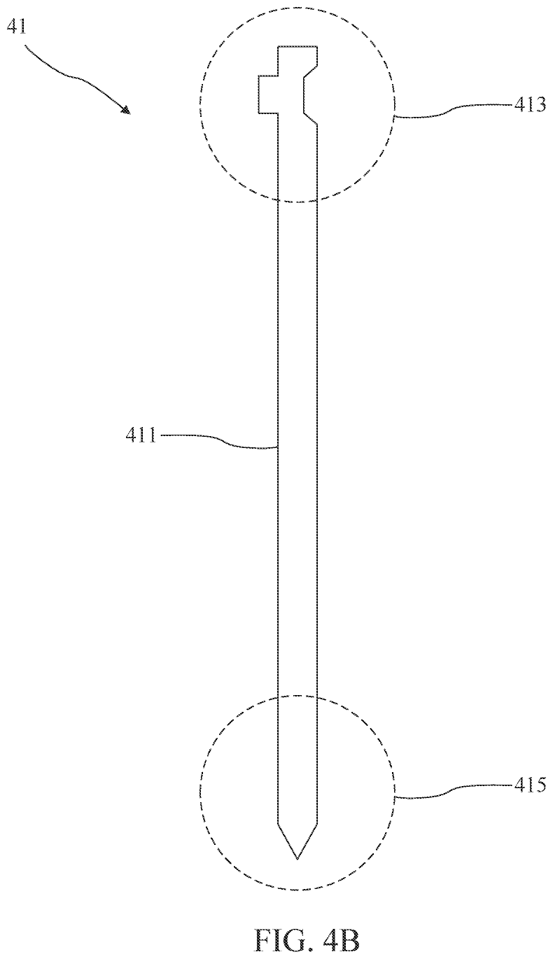

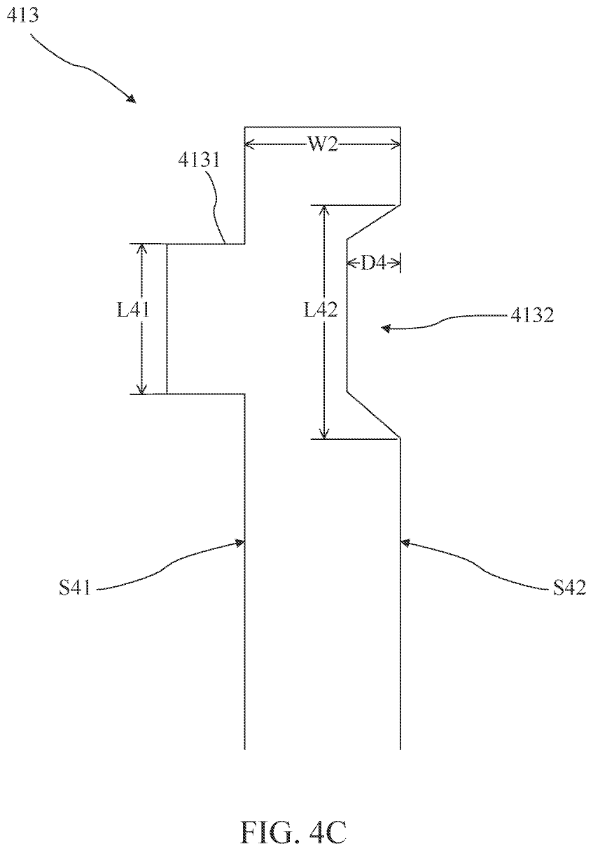

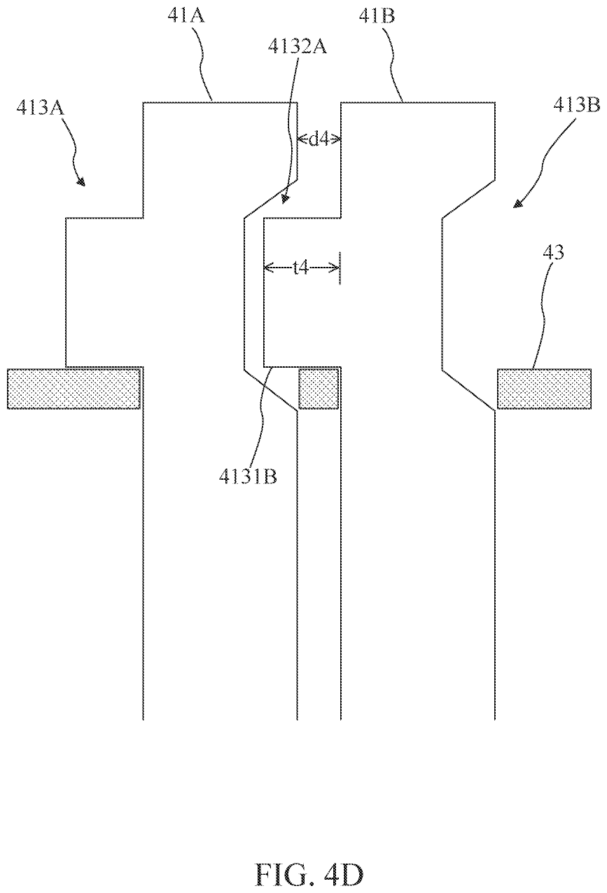

Please refer to FIG. 4A, which is a schematic view of a probe card device 4 according to some embodiments of the present disclosure. The probe card device 4 may include a plurality of probes 41, a first plate 43 and a second plate 45. The probes 41 may have a same shape, and may be arranged through the first plate 43 and the second plate 45.

In some embodiments, the first plate 43 may have a plurality of first through holes 430 for receiving the probes 41. The second plate 45 may have a plurality of second through holes 450 for receiving the probes 41. The first plate 43 and the second 45 may be parallel.

In some embodiments, the first through hole 430 and the second through hole 450 receiving a same probe 41 may be offset as viewed from a direction which is perpendicular to the first plate 43 and the second plate 45. In other words, the first through hole 430 and the second through hole 450 receiving a same probe 41 may be arranged in a non-aligned manner. Therefore, as shown in FIG. 4A, the probes 41 may be bent when being arranged through the first plate 43 and the second plate 45.

Please refer to FIG. 4B. FIG. 4B is a schematic view of the probe 41 according to some embodiments of the present disclosure. The probe 41 may include a body 411 and end portions 413, 415 of the body 411. The end portions 413 and 415 may be opposite. In some implementations, the end portion 413 may be a head of the probe 41, and the end portion 415 may be a tip of the probe 41 to touch an IC chip (not shown) for testing.

Please refer to FIG. 4C. FIG. 4C is an enlarged view of the end portion 413 of the body 411 according to an embodiment of the present disclosure. The end portion 413 may include a protrusion 4131 and a recess 4132.

In detail, the end portion 413 may have two sides S41 and S42 which are opposite. The protrusion 4131 may be disposed on the side S41 of the end portion 413 and protrude away from the end portion 413. The recess 4132 may be formed on the side S42 of the end portion 413 and be concave toward the end portion 413.

In some embodiments, a dimension of the recess 4132 may be greater than a dimension of a top portion of the protrusion 4131. In some implementations, a length L42 of an opening of the recess 4132 may be greater than a length L41 of the protrusion 4131. In some implementations, a depth D4 of the recess 4132 may be greater than a thickness of the top portion of the protrusion 4131.

Please refer to FIG. 4D. FIG. 4D is a schematic view of two adjacent probes 41A and 41B of the probes 41 according to some embodiments of the present disclosure.

When the probes 41A and 41B are arranged through the first plate 43, the protrusion 4131B of the probe 41B may extend into the recess 4132A of the probe 41A because a dimension of the recess 4132A is greater than a dimension of the top portion of the protrusion 4131B.

In some embodiments, because the protrusion 4131B of the probe 41B may extend into the recess 4132A of the probe 41A, a distance d4 between the end portion 413A and the end portion 413B may be less than a thickness t4 of the protrusion 4131B.

Further, when the recess 4132A of the probe 41A accommodates the protrusion 4131B of the probe 41B, the recess 4132A of the probe 41A and the protrusion 4131B of the probe 41B are near each other and should be separated to prevent the probes 41A and 41B from short circuiting. In other words, the recess 4132A of the probe 41A and the protrusion 4131B of the probe 41B are contactless.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

1. A probe, comprising:
a body; and
an end portion of the body, having:
a protrusion, disposed on a first side of the end portion; and
a recess, formed on a second side of the end portion;
wherein a dimension of the recess is greater than a dimension of a top portion of the protrusion, and the recess accommodates a protrusion of another probe when the probe is arranged through a plate.

2. The probe of claim 1, wherein the first side is opposite to the second site.

3. The probe of claim 1, wherein the protrusion protrudes away from the end portion and the recess is concave toward the end portion.

4. The probe of claim 1, wherein a depth of the recess is greater than a thickness of the top portion of the protrusion.

5. The probe of claim 1, wherein a depth of the recess is about 5% to 30% of a width of the end portion.

6. The probe of claim 1, wherein a length of an opening of the recess is greater than a length of the top portion of the protrusion.

7. The probe of claim 1, wherein the recess is tapered from outside of the end portion to inside of the end portion.

8. The probe of claim 1, wherein a shape of the recess includes a trapezoid, an arc or a rectangle.

9. The probe of claim 1, wherein a shape of the protrusion corresponds to a shape of the recess.

10. A probe, comprising:
a body; and
an end portion of the body, having:
a protrusion; and
a recess, having a shape for accommodating a protrusion of another probe when the probe is arranged through a plate.

11. The probe of claim 10, wherein the recess and the protrusion of the another probe are nearby when the probe and the another probe are arranged in an array and the shape of the recess accommodates the protrusion of the another probe.

12. The probe of claim 10, wherein a position of the recess corresponds to a position of the protrusion of the another probe when the probe and the another probe are arranged in an array.

13. A probe card device, comprising:
a first plate; and
a plurality of probes arranged through the first plate, including:
a first probe, having:
a first body; and
an end portion of the first body, having:
a first recess; and
a first protrusion; and
a second probe, having:
a second body; and
an end portion of the second body, having:
a second recess; and
a second protrusion, extending into the first recess.

14. The probe card device of claim 13, wherein a distance between the end portion of the first body and the end portion of the second body is less than a thickness of the second protrusion.

15. The probe card device of claim 13, wherein a shape of the second protrusion corresponds to a shape of the first recess.

16. The probe card device of claim 13, wherein a position of the second protrusion corresponds to a position of the first recess.

17. The probe card device of claim 13, wherein the first recess and the second protrusion are nearby.

18. The probe card device of claim 13, wherein the first plate has a plurality of first through holes for receiving the probes.

19. The probe card device of claim 18, further comprising:
a second plate, being parallel to the first plate and having a plurality of second through holes for receiving the probes.

20. The probe card device of claim 19, wherein the first through hole and the second through hole receiving a same probe are offset as viewed from a direction which is perpendicular to the first plate and the second plate.
